(19) United States
(12) Patent Application Publication
(10) Pub. No.: US 2024/0047511 A1
(43) Pub. Date: Feb. 8, 2024

(54) CAPACITOR AND SEMICONDUCTOR DEVICE INCLUDING THE SAME

(71) Applicant: Samsung Electronics Co., Ltd., Suwon-si (KR)

(72) Inventors: Jaeho LEE, Seoul (KR); Boeun PARK, Suwon-si (KR); Jeongil BANG, Suwon-si (KR)

(73) Assignee: Samsung Electronics Co., Ltd., Suwon-si (KR)

(21) Appl. No.: 18/145,597

(22) Filed: Dec. 22, 2022

(30) Foreign Application Priority Data
Aug. 4, 2022 (KR) 10-2022-0097578

(51) Int. Cl. H01G 4/008; H01G 4/10

(52) U.S. Cl. CPC H01L 28/75; H01G 4/008; H01G 4/10

(57) ABSTRACT

Provided are a capacitor and a semiconductor device including the capacitor. The capacitor and the semiconductor device include a first electrode; a second electrode provided apart from the first electrode, a dielectric film between the first electrode and the second electrode, and an interfacial film wholly or at least partially in contact with the dielectric film and having an electron affinity greater than an electron affinity of the dielectric film.

### CROSS-REFERENCE TO RELATED APPLICATION

This application is based on and claims priority under 35 U.S.C. § 119 to Korean Patent Application No. 10-2022-0097578, filed on Aug. 4, 2022, in the Korean Intellectual Property Office, the disclosure of which is incorporated by reference herein in its entirety.

### BACKGROUND

Various example embodiments relate to passive devices such as to capacitors configured to reduce leakage current and semiconductor devices including the capacitors.

Along with the down-scaling of integrated circuit devices, spaces for capacitors are also reduced. A capacitor includes an upper electrode, a lower electrode, and a dielectric film between the upper and lower electrodes, and dielectric materials having high permittivity are used in capacitors to obtain high capacitance. Leakage current may flow in a capacitor. Techniques for reducing leakage current flowing in a capacitor while minimizing or reducing the impact from a decrease in capacitance are needed/being pursued.

### SUMMARY

Provided are capacitors having good leakage current blocking characteristics.

Alternatively or additionally, provided are semiconductor devices including capacitors having good leakage current blocking characteristics.

However, embodiments are not limited thereto.

Additional aspects will be set forth in part in the description which follows and, in part, will be apparent from the description, or may be learned by practice of the presented embodiments of the disclosure.

According to various example embodiments, a capacitor includes a first electrode; a second electrode apart from the first electrode; a dielectric film between the first electrode and the second electrode; and an interfacial film wholly or at least partially in contact with the dielectric film and having an electron affinity greater than an electron affinity of the dielectric film.

A difference between the electron affinity of the interfacial film and the electron affinity of the dielectric film may be greater than about 0 eV and equal to or less than about 1.0 eV.

The dielectric film may include at least one selected from among or from the group consisting of Sr, Ti, Ba, Hf, and Zr.

The interfacial film may include an oxide or nitride including at least one selected from among or from the group consisting of Ti, Cr, Sn, W, Ta, Mo, Fe, and V.

The interfacial film may be between the first electrode and the dielectric film.

The interfacial film may be between the second electrode and the dielectric film.

The interfacial film may include: a first interfacial film between the first electrode and the dielectric film; and a second interfacial film between the second electrode and the dielectric film.

The interfacial film may have a lower permittivity than the dielectric film.

The interfacial film may be thinner than the dielectric film.

The interfacial film may have a thickness equal to or less than about 10% of a thickness of the dielectric film.

Either or both of the first electrode or the second electrode may be directly in contact with the dielectric film.

The capacitor may further include a plurality of sub-dielectric films between the first electrode and the second electrode.

The dielectric film and the interfacial film may include different materials.

The electron affinity of the dielectric film and the electron affinity of the interfacial film may be controlled by or may be based on at least one selected from among compositions of, growth directions of, and crystalline phases of the dielectric film and the interfacial film.

According to various example embodiments, a semiconductor device includes: a substrate; a gate structure provided on the substrate; a first source/drain region and a second source/drain region, which are in portions of the substrate; and a capacitor above the substrate. The capacitor includes: a first electrode; a second electrode apart from the first electrode; a dielectric film between the first electrode and the second electrode; and at least one interfacial film provided in contact with either or both of the first or second electrode and the dielectric film, wherein an electron affinity of the at least one interfacial film is greater than an electron affinity of the dielectric film.

A difference between the electron affinity of the at least one interfacial film and the electron affinity of the dielectric film may be greater than about 0 eV and equal to or less than about 1.0 eV.

The at least one interfacial film may be between the first electrode and the dielectric film.

The at least one interfacial film may be between the second electrode and the dielectric film.

The at least one interfacial film may include: a first interfacial film between the first electrode and the dielectric film; and a second interfacial film between the second electrode and the dielectric film.

The first electrode or the second electrode may be directly in contact with the dielectric film.

### BRIEF DESCRIPTION OF THE DRAWINGS

The above and other aspects, features, and advantages of certain example embodiments will be more apparent from the following description taken in conjunction with the accompanying drawings, in which:

FIG. 1 is a cross-sectional view illustrating a capacitor according to various example embodiments;

FIG. 2 is a graph illustrating a potential barrier with respect to an electron affinity difference between a dielectric film and an interfacial film;

FIG. 3 is a leakage current graph;

FIG. 4 is a cross-sectional view illustrating a capacitor according to various example embodiments;

FIG. 5 is a cross-sectional view illustrating a capacitor according to various example embodiments;

FIG. 6 is a cross-sectional view illustrating a capacitor according to various example embodiments;

FIG. 7 is a cross-sectional view illustrating a semiconductor device according to various example embodiments; and

FIGS. 8 and 9 are conceptual views schematically illustrating device architectures applicable to electronic apparatuses according to various example embodiments.

### DETAILED DESCRIPTION

Reference will now be made in detail to some embodiments, various examples of which are illustrated in the accompanying drawings, wherein like reference numerals refer to like elements throughout. In this regard, example embodiments may have different forms and should not be construed as being limited to the descriptions set forth herein. Accordingly, various embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described with reference to the accompanying drawings. In the drawings, like reference numerals refer to like elements, and the sizes of elements may be exaggerated for clarity of illustration. Example embodiments described herein are for illustrative purposes only, and various modifications may be made therein.

In the following description, when an element is referred to as being “above” or “on” another element, it may be directly on an upper, lower, left, or right side of the other element while making contact with the other element or may be above an upper, lower, left, or right side of the other element without making contact with the other element. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary, and are not limited to the stated order thereof.

As used herein, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples specific terms are just used herein to describe technical ideas and should not be considered for purposes of limitation unless defined by the claims.

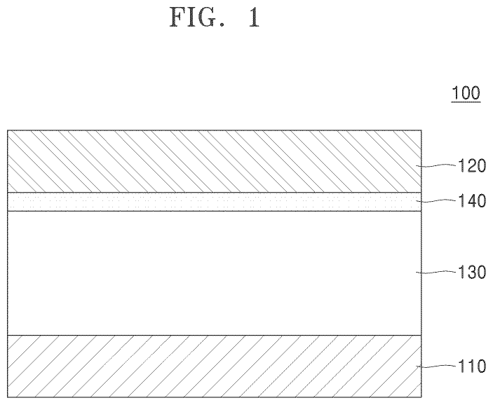

FIG. 1 is a cross-sectional view illustrating a capacitor 100 according to some example embodiments.

Referring to FIG. 1, the capacitor 100 may include a first electrode 110 (e.g. a lower electrode), a second electrode (e.g. an upper electrode) provided 120 provided apart from the first electrode 110, a dielectric film 130 provided between the first electrode 110 and the second electrode 120, and an interfacial film 140 provided in contact with the dielectric film 130 and having a greater electron affinity than the dielectric film 130. For scaling up within the limited thickness of the capacitor 100, at least one other interfacial film 140 may be additionally provided between the first electrode 110 that may be provided at a lower side of the capacitor 100, the second electrode 120 that may be provided on an upper side of the capacitor 100, and the dielectric film 130.

The material of the first electrode 110 may be selected such that the first electrode 110 has conductivity to function as an electrode and the capacitor 100 maintains a more stable capacitance even after a high-temperature manufacturing process.

The first electrode 110 may include a metal, a metal nitride, a metal oxide, or a combination thereof.

The second electrode 120 may be provided above the first electrode 110. The second electrode 120 may contact, e.g. may be directly in contact with the first electrode 110. The second electrode 120 may include a material for obtaining desired capacitance. As the degree of integration of an integrated circuit device including the capacitor 100 increases, a space for the capacitor 100 decreases accordingly, and thus a dielectric material having high permittivity may be used. The second electrode 120 may include a material having a high permittivity. The high permittivity may refer to a permittivity greater than the permittivity of a silicon oxide (e.g., greater than or equal to 3.9). The second electrode 120 may include a metal oxide, which includes at least one metal selected from the group consisting of or including Ca, Sr, Ba, Sc, Y, La, Ti, Hf, Zr, Nb, Ta, Ce, Pr, Nd, Gd, Dy, Yb, and Lu. For example, the second electrode 120 may include one or more of HfO₂, ZrO₂, CeO₂, La₂O₃, Ta₂O₃, or TiO₂. However, the second electrode 120 is not limited thereto.

The second electrode 120 may have a single-layer structure as shown in FIG. 1. However, the second electrode 120 is not limited thereto and may have a multilayer structure. The second electrode 120 may have a thickness sufficient for obtaining a desired capacitance. For example, the thickness of the second electrode 120 may be less than about 5 nanometers (nm). However, this is merely various example embodiments, and the second electrode 120 is not limited thereto.

The dielectric film 130 may be provided between the first electrode 110 and the second electrode 120. The dielectric film 130 may include a metal oxide, which includes a metal element included in the first electrode 110. For example, the interfacial film 140 may include an oxide and/or nitride, which includes at least one selected from the group consisting of or including Ti, Cr, Sn, W, Ta, Mo, Fe, and V. For example, the second electrode 120 and the dielectric film 130 may include different materials. In some example embodiments, the second electrode 130 may include one or more materials not included in the dielectric film 130, and/or the dielectric film 130 may include one or more materials not included in the second electrode 120.

The dielectric film 130 may be provided between the first electrode 110 and the second electrode 120 and/or between the interfacial film 140 and the second electrode 120.

The thickness of the dielectric film 130 may be less than the thickness of the first electrode 110. The content of carbon impurities in the dielectric film 130 may be less than or equal to about 1%. However, the dielectric film 130 is not limited thereto.

The thickness of the dielectric film 130 may be less than the thickness of the second electrode 120. The thickness of the interfacial film 140 may be less than or equal to about 10% of the thickness of the dielectric film 130. However, example embodiments are not limited thereto.

Each of the dielectric film 130 and the second electrode 120 may have intrinsic electron affinity, and the electron affinity of the interfacial film 140 may be greater than the electron affinity of the dielectric film 130. This will be described later.

In addition, the at least one interfacial film 140 additionally provided between the plurality of electrodes (the first electrode 110 and the second electrode 120) and the dielectric film 130 has an effect of buffering a work function difference between the plurality of electrodes and the dielectric film 130 when the plurality of electrodes and the dielectric film 130 are brought into contact with each other and the Fermi levels of the plurality of electrodes and the dielectric film 130 are aligned together. In the process of buffering, the potential barrier between the interfacial film 140 and the dielectric film 130 increases, and thus current leakage may be prevented or reduce. This will be described later.

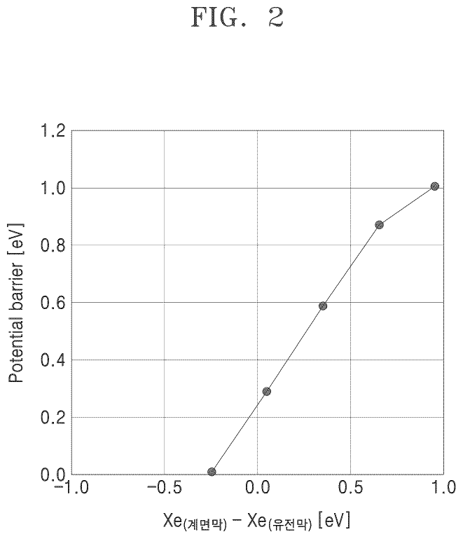

FIG. 2 is a graph illustrating a potential barrier with respect to the electron affinity difference between the dielectric film 130 and the interfacial film 140.

Electron affinity refers to the amount of energy (e.g., calories) released when 1 mole of gaseous atoms forms 1 mole of negative ions by obtaining 1 mole of electrons, and is the opposite of ionization energy.

In a PN junction, holes of a P-type region and electrons of a N-type region recombine with each other and disappear, leaving a row of negative ions, which have lost holes, in the P-type region and a row of positive ions, which have lost electrons, in the N-type region. Thus, the P-type region is negatively (−) charged and the N-type region is positively (+) charged, forming a potential slope. This potential slope is referred to as a potential barrier and/or as a transition region. The potential barrier prevents or reduces holes and electrons from flowing into each other, for example, into the opposite sides.

FIG. 2 shows a potential barrier with respect to the electron affinity difference between the interfacial film 140 and the dielectric film 130. When the electron affinity of the interfacial film 140 is less than or equal to the electron affinity of the dielectric film 130, the leakage current of the capacitor 100 may not be effectively controlled.

When the electron affinity of the interfacial film 140 is greater than the electron affinity of the dielectric film 130, the potential barrier shown in the Y-axis (the vertical axis) is greater than about 0.587 eV. As described above, as the potential barrier increases, a potential slope is formed across the charged regions, thereby reducing current leakage, for example, reducing the phenomenon in which holes and electrons flow into the opposite sides.

The electron affinity difference between the interfacial film 140 and the dielectric film 130 may be greater than about 0 eV but may be equal to or less than about 1.0 eV. However, example embodiments are not limited thereto.

In addition, the electron affinity of the dielectric film 130 and the interfacial film 140 may be adjusted by or affected by or be based upon at least one selected from the group consisting of or including the compositions of, growth directions of, and crystal phases of the dielectric film 130 and the interfacial film 140. For example, the interfacial film 140 may have greater electron affinity when the growth direction of the interfacial film 140 is (101) than when the growth direction of the interfacial film 140 is (110). However, this is merely a non-limiting example.

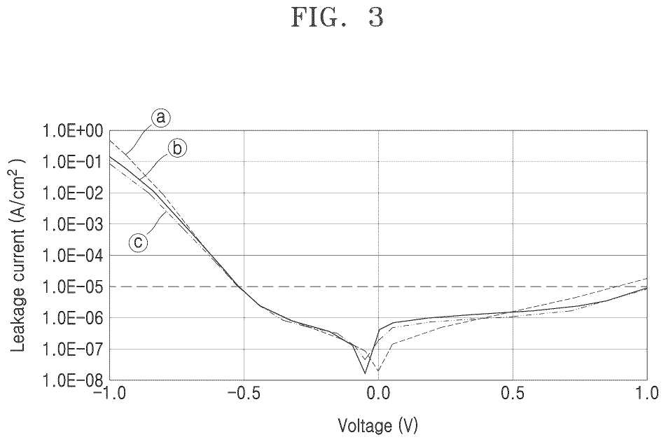

FIG. 3 is a graph illustrating leakage current of the capacitor 100 according to various example embodiments.

FIG. 3 shows a leakage current curve (a) when the capacitor 100 shown in FIG. 1 does not include the dielectric film 130, a leakage current curve (b) when the capacitor 100 shown in FIG. 1 includes an intermediate film, and a leakage current curve (c) when the capacitor 100 shown in FIG. 1 includes the dielectric film 130.

The capacitor 100 shown in FIG. 1 has less leakage current when including an intermediate film (refer to the curve (b)) than when having no dielectric film 130 (refer to the curve (a)). In addition, the capacitor 100 shown in FIG. 1 has less leakage current when including the dielectric film 130 (refer to the curve (c)) than when having no dielectric film 130 (refer to the curve (a)).

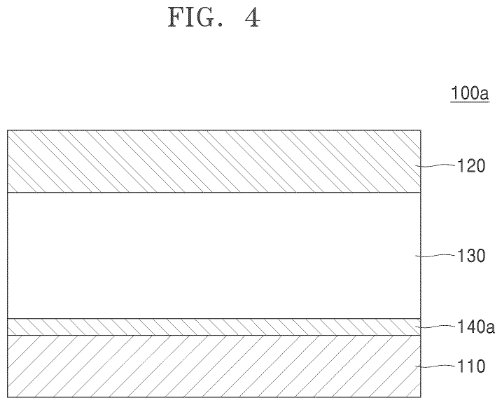

FIG. 4 is a cross-sectional view illustrating a capacitor 100a according to various example embodiments.

When FIG. 4 is compared with FIG. 1, an interfacial film 140a may be provided between a first electrode 110 and a dielectric film 130. The interfacial film 140a may reduce leakage current between the first electrode 110 and the dielectric film 130. The difference between the electron affinity of the interfacial film 140a and the electron affinity of the dielectric film 130 may be greater than about 0 eV but may be equal to or less than about 1.0 eV. However, example embodiments are not limited thereto. In addition, at least one interfacial film 140a may be provided between the first electrode 110 and the second electrode 120. For example, interfacial films 140a may be provided on both the upper and lower sides of the dielectric film 130. The thickness of the interfacial film 140a may be less than the thickness of the dielectric film 130. For example, the thickness of the interfacial film 140a may be equal to or less than about 10% of the thickness of the dielectric film 130. However, example embodiments are not limited thereto.

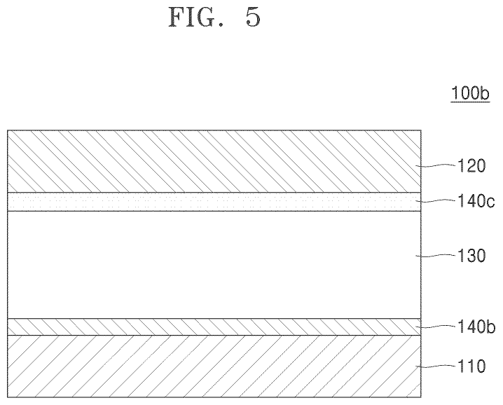

FIG. 5 is a cross-sectional view illustrating a capacitor 100b according to various example embodiments.

Referring to FIGS. 1 and 5, the capacitor 100b shown in FIG. 5 may include a first interfacial film 140b provided between a first electrode 110 and a dielectric film 130, and a second interfacial film 140c provided between the dielectric film 130 and a second electrode 120.

Both the first interfacial film 140b and the second interfacial film 140c may reduce leakage current between the plurality of electrodes (the first and second electrodes 110 and 120) and the dielectric film 130. At least one first interfacial film 140b and at least one second interfacial film 140b may be provided between the first electrode 110 and the second electrode 120 on upper and lower sides of the dielectric film 130. The thickness of each of the first interfacial film 140b and the second interfacial film 140b may be less than the thickness of the dielectric film 130. For example, the thickness of each of the first interfacial film 140b and the second interfacial film 140c may be less than or equal to about 10% of the thickness of the dielectric film 130. However, example embodiments are not limited thereto.

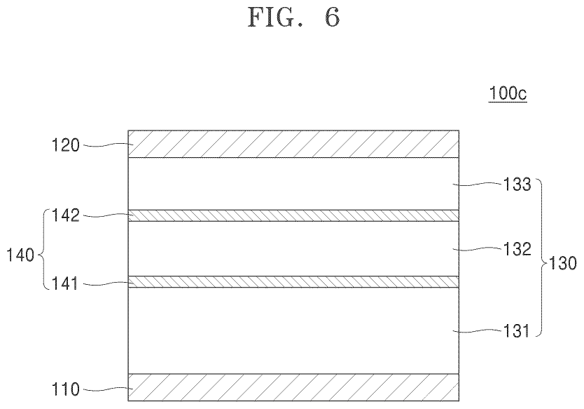

FIG. 6 is a cross-sectional view illustrating a capacitor 100c according to various example embodiments.

Referring to FIG. 6, the capacitor 100c is not limited to having one dielectric film. For example, the capacitor 100c may have a plurality of sub-dielectric films. For example, a dielectric film 130 may include first to third sub-dielectric films 131, 132, and 133 which are sequentially arranged.

The first to third sub-dielectric films 131, 132, and 133 may have different physical characteristics. For example, the first to third sub-dielectric films 131, 132, and 133 may have different conductance and capacitance characteristics. At least two of the first to third sub-dielectric films 131, 132, and 133 may include different materials. For example, the first sub-dielectric film 131 and the second sub-dielectric film 132 may include different materials, and the second sub-dielectric film 132 and the third sub-dielectric film 133 may include the same material. However, embodiments are not limited thereto. The first to third sub-dielectric films 131, 132, and 133 may include the same material and/or different materials. Even when the first to third sub-dielectric films 131, 132, and 133 include the same material, the first to third sub-dielectric films 131, 132, and 133 may have different physical characteristics such as conductance and/or capacitance characteristics, which may be based upon or according to the crystal structures thereof.

The dielectric film 130 may further include a plurality of interfacial films such as first and second interfacial films 141 and 142 according to the arrangement of the first to third sub-dielectric films 131, 132, and 133.

The first and second interfacial films 141 and 142 may have different physical characteristics and may include different manufactures. However, example embodiments are not limited thereto.

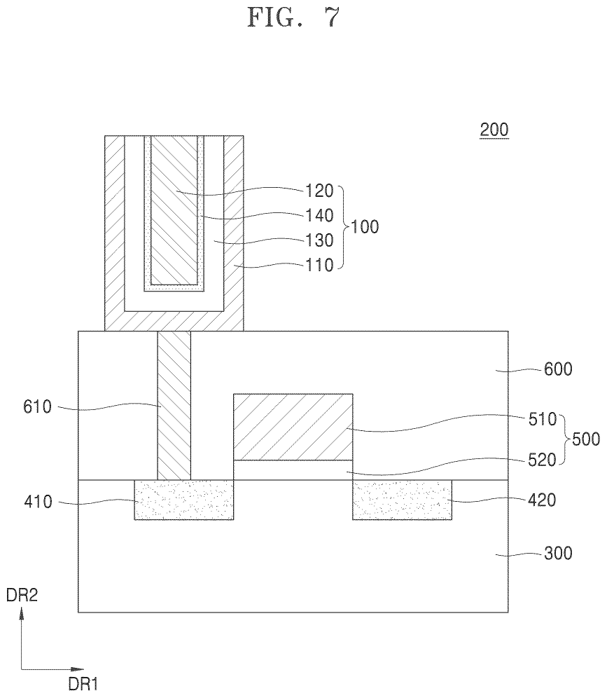

FIG. 7 is a cross-sectional view illustrating a semiconductor device 200 according to various example embodiments. For conciseness of description, substantially the same elements as those described with reference to FIG. 1 may not be described.

Referring to FIG. 7, the semiconductor device 200 may include a substrate 300, a gate structure 500, an interlayer insulating film 600, a contact 610, and a capacitor 100. The substrate 300 may include a semiconductor substrate. For example, the substrate 300 may include one or more of a silicon substrate, a germanium substrate, or a silicon-germanium substrate.

A first source/drain region 410 and a second source/drain region 420 may be provided in upper portions of the substrate 300. The first and second sources/drain regions 410 and 420 may be apart from each other in a first direction DR1 parallel to an upper surface of the substrate 300. Each of the first and second sources/drain regions 410 and 420 may be formed by implanting a dopant, such as one or more of boron, phosphorus, or arsenic, into the substrate 300.

The gate structure 500 may be provided on the substrate 300. The gate structure 500 may be provided between the first and second sources/drain regions 410 and 420. The gate structure 500 may include a gate electrode 510 and a gate insulating film 520. The gate electrode 510 may include a conductive material. For example, the gate electrode 510 may include a metal and/or polysilicon.

The gate insulating film 520 may be provided between the gate electrode 510 and the substrate 300. The gate insulating film 520 may insulate the substrate 300 from the gate electrode 510. The gate insulating film 520 may include a dielectric material. For example, the gate insulating film 520 may include one or more of a silicon oxide (for example, SlO₂), an aluminum oxide (for example, Al₂O₃), or a material having high permittivity (for example, HfO₂).

The interlayer insulating film 600 may be provided on the substrate 300 to cover or at least partially cover the gate structure 500. The interlayer insulating film 600 may include an insulating material. For example, the interlayer insulating film 600 may include one or more of a silicon oxide (for example, SlO₂), an aluminum oxide (for example, Al₂O₃), or a material having high permittivity (for example, HfO₂).

The capacitor 100 may be provided on the interlayer insulating film 600. The capacitor 100 may include a first electrode 110, an interfacial film 140, a second electrode 120, and a dielectric film 130. The first electrode 110, the interfacial film 140, the second electrode 120, and the dielectric film 130 may be respectively the same as the first electrode 110, the interfacial film 140, the second electrode 120, and the dielectric film 130 which are described with reference to FIG. 1.

The contact 610 may be provided between the first electrode 110 and the first source/drain region 410. The contact 610 may penetrate or at least partially penetrate the interlayer insulating film 600. The contact 610 may electrically connect the first electrode 110 and the first source/drain region 410 to each other. The contact 610 may include a conductive material (for example, a metal).

The dielectric film 130 may have leakage current blocking characteristics while reducing a decrease in the capacitance of the capacitor 100. According to various example embodiments, the capacitor 100 may include the dielectric film 130 and the interfacial film 140 as leakage current reducing layers. Therefore, the stability and/or the reliability of the semiconductor device 200 may be improved.

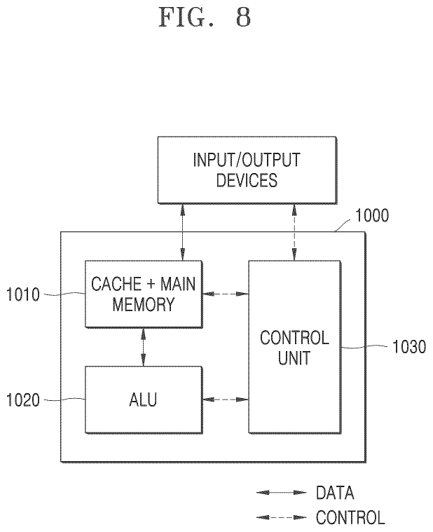

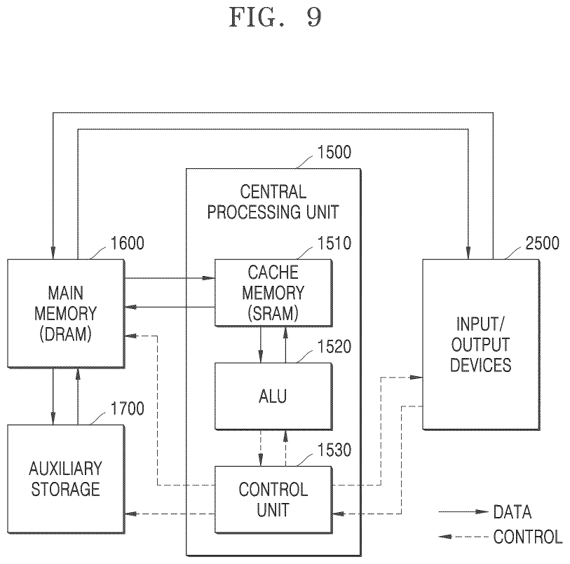

FIGS. 8 and 9 are conceptual views schematically illustrating electronic device architectures appliable to electronic apparatuses according to example embodiments.

Referring to FIG. 8, an electronic device architecture 1000 may include a memory unit 1010 and a control unit 1030. The electronic device architecture 1000 may further include an arithmetic logic unit (ALU) 1020. The memory unit 1010, the ALU 1020, and the control unit 1030 may be electrically connected to each other. For example, the electronic device architecture 1000 may be implemented as one chip including the memory unit 1010, the ALU 1020, and the control unit 1030. For example, the memory unit 1010, the ALU 1020, and the control unit 1030 may be interconnected with each other on a chip through metal lines for direct communication with each other, such as direct one-way and/or two-way and/or broadcast communication with each other. The memory unit 1010, the ALU 1020, and the control unit 1030 may be monolithically integrated on a single substrate to form a single chip. Input/output devices may be connected to the electronic device architecture (chip) 1000. In addition, the memory unit 1010 may include both a main memory and a cache memory. The electronic device architecture (chip) 1000 may be an on-chip memory processing unit. The memory unit 1010, the ALU 1020, and/or the control unit 1030 may independently include the capacitor 100, 100a, 100b, or 100c described in various embodiments.

Referring to FIG. 9, a cache memory 1510, an ALU 1520, and a control unit 1530 may form a central processing unit (CPU) 1500, and the cache memory 1510 may include a static random-access memory (SRAM). A main memory 1600 and an auxiliary storage 1700 may be provided separately from the CPU 1500. In addition, input/output devices 2500 may be provided separately from the CPU 1500. The main memory 1600 may include, for example, a dynamic random-access memory (DRAM) including one or more of the capacitor 100, 100a, 100b, or 100c described in the various embodiments.

In some cases, the electronic device architectures may be implemented in the form in which unit computing devices and unit memory devices are adjacent to each other on one chip without any distinction between sub-units.

While the capacitors and the electronic devices including the capacitors have been described according to the embodiments with reference to the accompanying drawings, embodiments are merely examples, and those of ordinary skill in the art will understand that the scope covers various modifications and equivalents. Therefore, the embodiments should be considered in a descriptive sense only and not for purposes of limitation. The scope is defined not by the detailed description but by various claims, and all differences within the scope will be construed as being included in example embodiments.

As described above, according to the one or more example embodiments, the capacitor and the semiconductor device including the capacitor includes the first electrode, the second electrode, the dielectric film, and additionally the interfacial film having greater electron affinity than the dielectric film. Therefore, leakage current of the capacitor may be reduced. According to the one or more of the above embodiments, the current leakage characteristics and/or capacitance characteristics of the capacitor may be improved. According to the one or more of the above embodiments, the current leakage characteristics and/or capacitance characteristics of the semiconductor device including the capacitor may be improved.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various embodiments have been described, embodiments are merely examples, and it will be understood by those of ordinary skill in the art that various modifications may be made in various example embodiments.

It should be understood that various example embodiments described herein should be considered in a descriptive sense only and not for purposes of limitation. Descriptions of features or aspects within each example embodiment should typically be considered as available for other similar features or aspects in other example embodiments, and example embodiments are not necessarily mutually exclusive with one another. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
a second electrode apart from the first electrode;
a dielectric film between the first electrode and the second electrode; and
an interfacial film at least partially in contact with the dielectric film and having an electron affinity greater than an electron affinity of the dielectric film.

2. The capacitor of claim 1, wherein a difference between the electron affinity of the interfacial film and the electron affinity of the dielectric film is greater than about 0 eV and less than or equal to about 1.0 eV.

3. The capacitor of claim 1, wherein the dielectric film comprises at least one selected from among Sr, Ti, Ba, Hf, and Zr.

4. The capacitor of claim 1, wherein the interfacial film comprises an oxide or nitride comprising at least one selected from among Ti, Cr, Sn, W, Ta, Mo, Fe, and V.

5. The capacitor of claim 1, wherein the interfacial film is between the first electrode and the dielectric film.

6. The capacitor of claim 1, wherein the interfacial film is between the second electrode and the dielectric film.

7. The capacitor of claim 1, wherein the interfacial film comprises:
a first interfacial film between the first electrode and the dielectric film; and
a second interfacial film between the second electrode and the dielectric film.

8. The capacitor of claim 1, wherein the interfacial film has a lower permittivity than the dielectric film.

9. The capacitor of claim 1, wherein the interfacial film is thinner than the dielectric film.

10. The capacitor of claim 9, wherein the interfacial film has a thickness less than or equal to about 10% of a thickness of the dielectric film.

11. The capacitor of claim 1, wherein either or both of the first electrode or the second electrode is directly in contact with the dielectric film.

12. The capacitor of claim 1, further comprising:
a plurality of sub-dielectric films between the first electrode and the second electrode.

13. The capacitor of claim 1, wherein the dielectric film and the interfacial film comprise different materials.

14. The capacitor of claim 1, wherein the electron affinity of the dielectric film and the electron affinity of the interfacial film are based on at least one selected from among compositions of, growth directions of, and crystalline phases of the dielectric film and the interfacial film.

15. A semiconductor device comprising:
a substrate;
a gate structure on the substrate;
a first source/drain region and a second source/drain region in upper portions of the substrate; and
a capacitor above the substrate;
wherein the capacitor comprises:
a first electrode;
a second electrode apart from the first electrode;
a dielectric film between the first electrode and the second electrode; and
at least one interfacial film in contact with either or both of the first or second electrode and the dielectric film,
wherein an electron affinity of the at least one interfacial film is greater than an electron affinity of the dielectric film.

16. The semiconductor device of claim 15, wherein difference between the electron affinity of the at least one interfacial film and the electron affinity of the dielectric film is greater than about 0 eV and less than or equal to about 1.0 eV.

17. The semiconductor device of claim 15, wherein the at least one interfacial film is between the first electrode and the dielectric film.

18. The semiconductor device of claim 15, wherein the at least one interfacial film is between the second electrode and the dielectric film.

19. The semiconductor device of claim 15, wherein the at least one interfacial film comprises:
a first interfacial film between the first electrode and the dielectric film; and
a second interfacial film between the second electrode and the dielectric film.

20. The semiconductor device of claim 15, wherein either or both of the first electrode or the second electrode is directly in contact with the dielectric film.
